(19) United States
(12) Patent Application Publication
(10) Pub. No.: US 2023/0420265 A1
(43) Pub. Date: Dec. 28, 2023

(54) ANISOTROPIC WET ETCHING IN PATTERNING

(71) Applicant: Taiwan Semiconductor Manufacturing Company, Ltd., Hsinchu (TW)

(72) Inventors: Tefu Yeh, Kaohsiung (TW); Cheng-Chieh Tu, Tainan (TW); Ming-Chi Huang, Hsinchu (TW); Ying-Liang Chuang, Hsinchu (TW); Ming-Hsi Yeh, Hsinchu (TW); Kuo-Bin Huang, Hsinchu (TW)

(73) Assignee: Taiwan Semiconductor Manufacturing Company, Ltd., Hsinchu (TW)

(21) Appl. No.: 17/808,175

(22) Filed: Jun. 22, 2022

(51) Int. Cl. H01L 21/3213

(52) U.S. Cl. CPC H01L 21/32134

(57) ABSTRACT

Disclosed is a method comprising: providing at least two structures with a metal layer over each; forming a patterned photolithographic layer over the metal layer over the first structure; removing the metal layer from the second structure via wet etch operations using a chemical etchant that is resistant to penetration into the photolithographic layer; and achieving, after wet etch operations, a remaining metal ratio of a distance X over a distance Y that is less than 179 and greater than 1, wherein X is the distance from a first line extending from an edge of the metal layer over the first structure to a second line extending from an edge of a channel region in the second structure, and Y is a second distance from the first line to a third line extending from an edge of the metal layer formed over the channel region in the first structure.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart depicting an example method of semiconductor fabrication including fabrication of multi-gate devices, in accordance with some embodiments.

FIGS. 2A, 3A, 4A, 5A, 6A, 7A, 8A, 9A and 10A, are isometric views of an example semiconductor device, in accordance with some embodiments.

FIGS. 2B, 3B, 4B, 5B, 6B, 7B, 8B, 9B and 10B are corresponding cross-sectional side views of an embodiment of the example semiconductor device along a first cut X-X′, in accordance with some embodiments.

FIG. 11 is a schematic diagram illustrating an example semiconductor structure 100 in a two-dimensional view at one stage during fabrication of a semiconductor device, in accordance with some embodiments.

FIG. 12 is a process flow chart depicting an example process for forming gate metal around a multi-gate device in a semiconductor device, in accordance with some embodiments.

FIGS. 13A is a schematic diagram of a 3-D (three-dimensional) semiconductor device at one stage of fabrication, in accordance with some embodiments.

FIGS. 13B is a cross-sectional view of the 3-D semiconductor device depicted in FIG. 3A, taken along a cut line A-A along the y-axis, in accordance with some embodiments.

FIGS. 13C-3G, are cross-sectional views of the 3-D semiconductor device depicted in FIG. 3A, taken along the cut line A-A along the y-axis, at various stages of fabrication, in accordance with some embodiments.

FIG. 14 is a process flow chart depicting another example process for forming gate metal around a multi-gate device in a semiconductor device, in accordance with some embodiments.

FIGS. 15A-15E, are cross-sectional views of a semiconductor device at various stages of fabrication, in accordance with some embodiments.

FIGS. 16A and 16B are block diagrams illustrating effects that may be achieved from chemical tuning of an etchant solution to achieve anisotropic wet etching, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting.

For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present. When an element or layer is referred to as being “on” another element or layer, it is directly on and in contact with the other element or layer.

Certain embodiments herein are generally related to multi-gate transistors. Multi-gate transistors include those transistors whose gate structures are formed on at least two-sides of a channel region. These multi-gate devices may include a p-type metal-oxide-semiconductor device or an n-type metal-oxide-semiconductor multi-gate device. Specific examples may be presented and referred to herein as a gate-all-around (GAA) device. A GAA device includes any device that has its gate structure, or portion thereof, formed on 4-sides of a channel region (e.g., surrounding a portion of a channel region).

Structures presented herein also include embodiments that have channel regions in the form of nanosheets. The term “nanosheet” designates any material portion with nanoscale, or even microscale dimensions, and having an elongate shape, regardless of the cross-sectional shape of this portion. Thus, this term designates both circular and substantially circular cross-section elongate material portions, e.g., nanowires, and beam or bar-shaped material portions including for example a cylindrical or substantially rectangular cross-section.

Presented herein are embodiments that may have one or more channel regions associated with a single, contiguous gate structure. However, one of ordinary skill would recognize that the teaching can apply to a single channel region or any number of channel regions. One of ordinary skill may recognize other examples of semiconductor devices that may benefit from aspects of the present disclosure.

Embodiments will now be described with respect to particular examples including FinFET manufacturing processes with unwanted lateral etching reduction during wet etching operations. However, embodiments are not limited to the examples provided herein, and the ideas may be implemented in a wide array of embodiments.

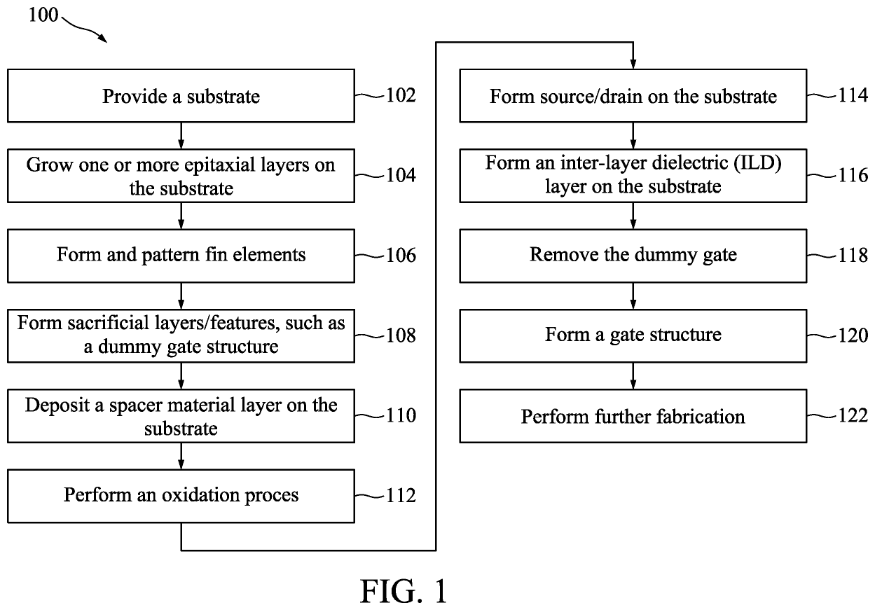

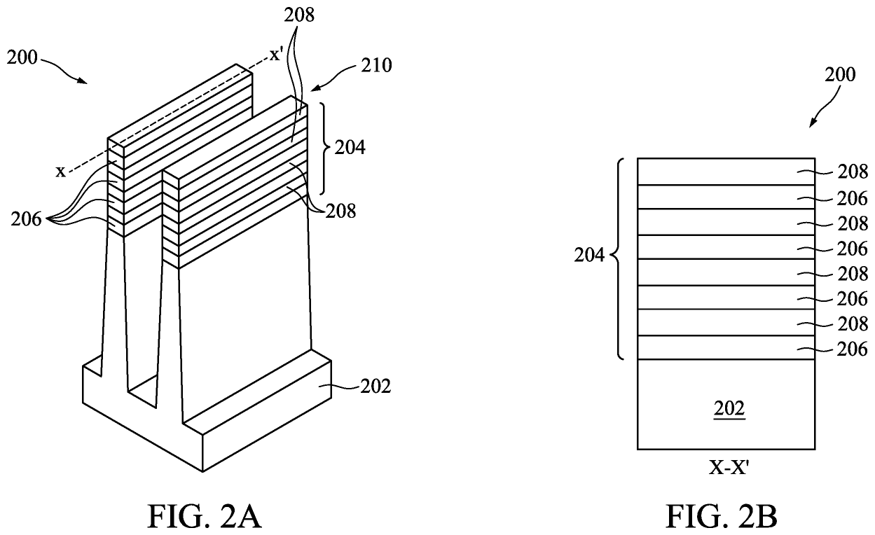

FIG. 1 is a flow chart depicting an example method 100 of semiconductor fabrication including fabrication of multi-gate devices. FIG. 1 is described in conjunction with FIGS. 2A-2B, 3A-3B, 4A-4B, 5A-5B, 6A-6B, 7A-7B, 8A-8B, 9A-9B and 10A-10B, which illustrate a semiconductor device or structure at various stages of fabrication in accordance with some embodiments. The method 100 is merely an example and is not intended to limit the present disclosure beyond what is explicitly recited in the claims. Additional steps may be provided before, during, and after method 100, and some of these steps describe can be moved, replaced, or eliminated for additional embodiments of method 100. Additional features may be added in the semiconductor device depicted in the figures, and some of the features described below can be replaced, modified, or eliminated in other embodiments.

As with the other method embodiments and exemplary devices discussed herein, it is understood that parts of the semiconductor devices may be fabricated by typical semiconductor technology process flow, and thus some processes are only briefly described herein. Further, the exemplary semiconductor devices may include various other devices and features, such as other types of devices such as additional transistors, bipolar junction transistors, resistors, capacitors, inductors, dials, fuses, and or other logic devices, etc., but is simplified for better understanding of concepts of the present disclosure. In some embodiments, exemplary devices include a plurality of semiconductor devices (e.g., transistors), including PFETs, NFETs, etc., which may be interconnected. Moreover, it is noted that the process steps of method 100, include any descriptions given with reference to the figures, as with the remainder of the method and exemplary figures provided in this disclosure, are merely exemplary and are not intended to be limiting beyond what is specifically recited in the claims that follow.

FIGS. 2A, 3A, 4A, 5A, 6A, 7A, 8A, 9A and 10A, are isometric views of an example semiconductor device 200 and FIGS. 2B, 3B, 4B, 5B, 6B, 7B, 8B, 9B and 10B are corresponding cross-sectional side views of an embodiment of the example semiconductor device 200 along a first cut X-X′ in an example process fabrication process in accordance with some embodiments. In some figures, some reference numbers of components or features illustrated therein may be omitted to avoid obscuring other components or features; this is for ease of depicting the figures.

At block 102, the example method 100 includes providing a substrate. Referring to the example of FIGS. 2A and 2B, in an embodiment of block 102, a substrate 202 is provided. In some embodiments, the substrate 202 may be a semiconductor substrate such as a silicon substrate. The substrate 202 may include various layers, including conductive or insulating layers formed on a semiconductor substrate. The substrate 202 may include various doping configurations depending on design requirements as is known in the art. For example, different doping profiles (e.g., n wells, p wells) may be formed on the substrate 202 in regions designed for different device types (e.g., n-type field effect transistors (NFET), p-type field effect transistors (PFET)). The suitable doping may include ion implantation of dopants and/or diffusion processes. The substrate 202 typically has isolation features (e.g., shallow trench isolation (STI) features) interposing the regions providing different device types. The substrate 202 may also include other semiconductors such as germanium, silicon carbide (SiC), silicon germanium (SiGe), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) structure, and/or have other suitable enhancement features.

Returning to FIG. 1, the method 100 then proceeds to block 104 where one or more epitaxial layers are grown on the substrate. With reference to the example of FIGS. 2A and 2B, in an embodiment of block 104, an epitaxial stack 204 is formed over the substrate 202. The epitaxial stack 204 includes epitaxial layers 206 of a first composition interposed by epitaxial layers 208 of a second composition. The first and second composition can be different. In an embodiment, the epitaxial layers 206 are SiGe and the epitaxial layers 208 are silicon (Si). However, other embodiments are possible including those that provide for a first composition and a second composition having different oxidation rates and/or etch selectivity. In some embodiments, the epitaxial layer 206 includes SiGe and where the epitaxial layer 208 includes Si, the Si oxidation rate of the epitaxial layer 208 is less than the SiGe oxidation rate of the epitaxial layer 206.

The epitaxial layers 208 or portions thereof may form a channel region of the multi-gate device 200. For example, the epitaxial layers 208 may be referred to as “nanowires” used to form a channel region of a multi-gate device 200 such as a GAA device. These “nanowires” are also used to form portions of the source/drain features of the multi-gate device 200 as discussed below. Again, as the term is used herein, “nanowires” refers to semiconductor layers that are cylindrical in shape as well as other configurations such as, bar-shaped. The use of the epitaxial layers 208 to define a channel or channels of a device is further discussed below.

It is noted that four (4) layers of each of epitaxial layers 206 and 208 are illustrated in FIGS. 2A and 2B, this is for illustrative purposes only and not intended to be limiting beyond what is specifically recited in the claims. It can be appreciated that any number of epitaxial layers can be formed in the epitaxial stack 204; the number of layers depending on the desired number of channels regions for the device 200. In some embodiments, the number of epitaxial layers 208 is between 2 and 10.

In some embodiments, the epitaxial layer 206 has a thickness range of about 2-6 nanometers (nm). The epitaxial layers 206 may be substantially uniform in thickness. In some embodiments, the epitaxial layer 208 has a thickness range of about 6-12 nm. In some embodiments, the epitaxial layers 208 of the stack are substantially uniform in thickness. As described in more detail below, the epitaxial layer 208 may serve as channel region(s) for a subsequently-formed multi-gate device and its thickness chosen based on device performance considerations. The epitaxial layer 206 may serve to define a gap distance between adjacent channel region(s) for a subsequently-formed multi-gate device and its thickness chosen based on device performance considerations.

By way of example, epitaxial growth of the layers of the stack 204 may be performed by a molecular beam epitaxy (MBE) process, a metalorganic chemical vapor deposition (MOCVD) process, and/or other suitable epitaxial growth processes. In some embodiments, the epitaxially grown layers such as, the layers 208 include the same material as the substrate 202. In some embodiments, the epitaxially grown layers 206, 208 include a different material than the substrate 202. As stated above, in at least some examples, the epitaxial layer 206 includes an epitaxially grown silicon germanium (SiGe) layer and the epitaxial layer 208 includes an epitaxially grown silicon (Si) layer. Alternatively, in some embodiments, either of the epitaxial layers 206, 208 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the epitaxial layers 206, 208 may be chosen based on providing differing oxidation, etch selectivity properties. In various embodiments, the epitaxial layers 206, 208 are substantially dopant-free (i.e., having an extrinsic dopant concentration from about 0 cm−3 to about 1×1017 cm−3), where for example, no intentional doping is performed during the epitaxial growth process.

The method 100 then proceeds to block 106 where fin elements are patterned and formed. With reference to the example of FIG. 2A, in an embodiment of block 106, a plurality of fin elements 210 extending from the substrate 202 are formed. In various embodiments, each of the fin elements 210 includes a substrate portion formed from the substrate 202, portions of each of the epitaxial layers of the epitaxial stack including epitaxial layers 206 and 208.

The fin elements 210 may be fabricated using suitable processes including photolithography and etch processes. The photolithography process may include forming a photoresist layer over the substrate 202 (e.g., over the epi stack 204), exposing the resist to a pattern, performing post-exposure bake processes, and developing the resist to form a masking element including the resist. In some embodiments, pattering the resist to form the masking element may be performed using an electron beam (e-beam) lithography process. The masking element may then be used to protect regions of the substrate 202, and layers 204 formed thereupon, while an etch process forms trenches in unprotected regions through masking layer(s) such as hard mask, thereby leaving the plurality of extending fins. The trenches may be etched using a dry etch (e.g., reactive ion etching), a wet etch, and/or other suitable processes. The trenches may be filled with dielectric material forming, for example, shallow trench isolation features interposing the fins.

In some embodiments, the dielectric layer may include SiO2, silicon nitride, silicon oxynitride, fluorine-doped silicate glass (FSG), a low-k dielectric, combinations thereof, and/or other suitable materials known in the art. In various examples, the dielectric layer may be deposited by a chemical vapor deposition (CVD) process, a sub atmospheric CVD (SACVD) process, a flowable CVD process, an atomic layer deposition (ALD) process, a physical vapor deposition (PVD) process, and/or other suitable process. In some embodiments, after deposition of the dielectric layer, the device 200 may be annealed, for example, to improve the quality of the dielectric layer. In some embodiments, the dielectric layer (and subsequently formed STI features 302) may include a multi-layer structure, for example, having one or more liner layers.

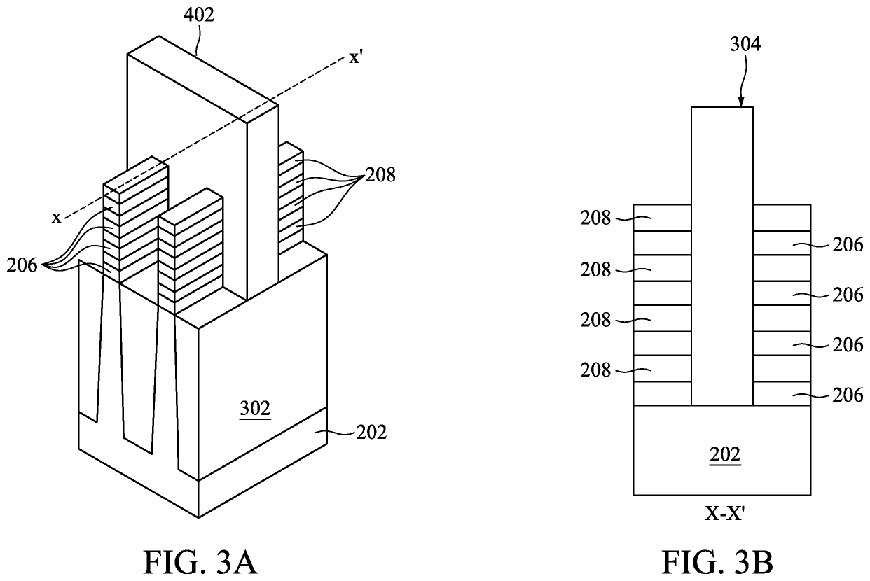

In some embodiments of forming the isolation (STI) features, after deposition of the dielectric layer, the deposited dielectric material is thinned and planarized, for example by a chemical mechanical polishing (CMP) process. The CMP process may planarize the top surface thereby forming STI features 302. The STI features 302 interposing the fin elements are recessed. Referring to the example of FIG. 3A, the STI features 302 are recessed providing the fins 210 extending above the STI features 302. In some embodiments, the recessing process may include a dry etching process, a wet etching process, and/or a combination thereof. In some embodiments, a recessing depth is controlled (e.g., by controlling an etching time) so as to result in a desired height ‘H’ of the exposed upper portion of the fin elements 210. The height ‘H’ exposes each of the layers of the epitaxy stack 204.

Numerous other embodiments of methods to form the fins on the substrate may also be used including, for example, defining the fin region (e.g., by mask or isolation regions) and epitaxially growing the epitaxial stack 204 in the form of the fin. In some embodiments, forming the fins may include a trim process to decrease the width of the fins. The trim process may include wet or dry etching processes.

The method 100 then proceeds to block 108 where sacrificial layers/features are formed and in particular, a dummy gate structure. While the present discussion is directed to a replacement gate process whereby a dummy gate structure is formed and subsequently replaced, other configurations may be possible.

With reference to FIGS. 3A and 3B, a gate stack 304 is formed. In an embodiment, the gate stack 304 is a dummy (sacrificial) gate stack that is subsequently removed as discussed with reference to block 108 of the method 100.

Thus, in some embodiments using a gate-last process, the gate stack 304 is a dummy gate stack and will be replaced by the final gate stack at a subsequent processing stage of the device 200. In particular, the gate stack 304 may be replaced at a later processing stage by a high-K dielectric layer (HK) and metal gate electrode (MG) as discussed below. In some embodiments, the gate stack 304 is formed over the substrate 202 and is at least partially disposed over the fin elements 210. The portion of the fin elements 210 underlying the gate stack 304 may be referred to as the channel region. The gate stack 304 may also define a source/drain region of the fin elements 210, for example, the regions of the fin and epitaxial stack 204 adjacent and on opposing sides of the channel region.

In some embodiments, the gate stack 304 includes the dielectric layer and a dummy electrode layer. The gate stack 304 may also include one or more hard mask layers (e.g., oxide, nitride). In some embodiments, the gate stack 304 is formed by various process steps such as layer deposition, patterning, etching, as well as other suitable processing steps. Exemplary layer deposition processes includes CVD (including both low-pressure CVD and plasma-enhanced CVD), PVD, ALD, thermal oxidation, e-beam evaporation, or other suitable deposition techniques, or combinations thereof. In forming the gate stack for example, the patterning process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods.

As indicated above, the gate stack 304 may include an additional gate dielectric layer. For example, the gate stack 304 may include silicon oxide. Alternatively or additionally, the gate dielectric layer of the gate stack 304 may include silicon nitride, a high-K dielectric material or other suitable material. In some embodiments, an electrode layer of the gate stack 304 may include polycrystalline silicon (polysilicon). Hard mask layers such as SiO2, Si3N4, silicon oxynitride, alternatively include silicon carbide, and/or other suitable compositions may also be included.

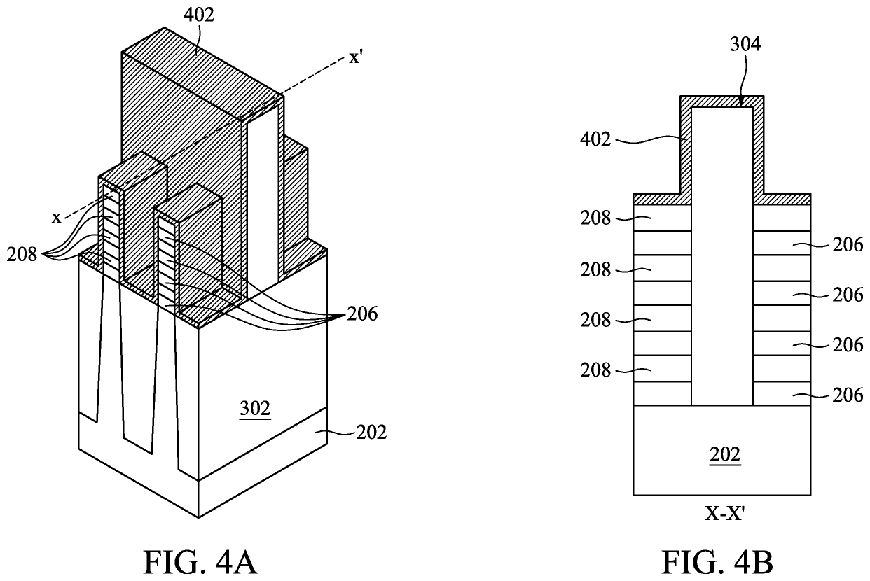

The method 100 then proceeds to block 110 where a spacer material layer is deposited on the substrate. Referring to the example of FIGS. 4A and 4B, a spacer material layer 402 is disposed on the substrate 202. The spacer layer 402 may include a dielectric material such as silicon oxide, silicon nitride, silicon carbide, silicon oxynitride, SiCN films, silicon oxycarbide, SiOCN films, and/or combinations thereof. In some embodiments, the spacer material layer 402 includes multiple layers, such as main spacer walls, liner layers, and the like. By way of example, the spacer material layer 402 may be formed by depositing a dielectric material over the gate stack 304 using processes such as, CVD process, a sub atmospheric CVD (SACVD) process, a flowable CVD process, an ALD process, a PVD process, or other suitable process. It is noted that the spacer conformal layer 402 is illustrated in FIG. 4B as covering the epitaxial stack 204.

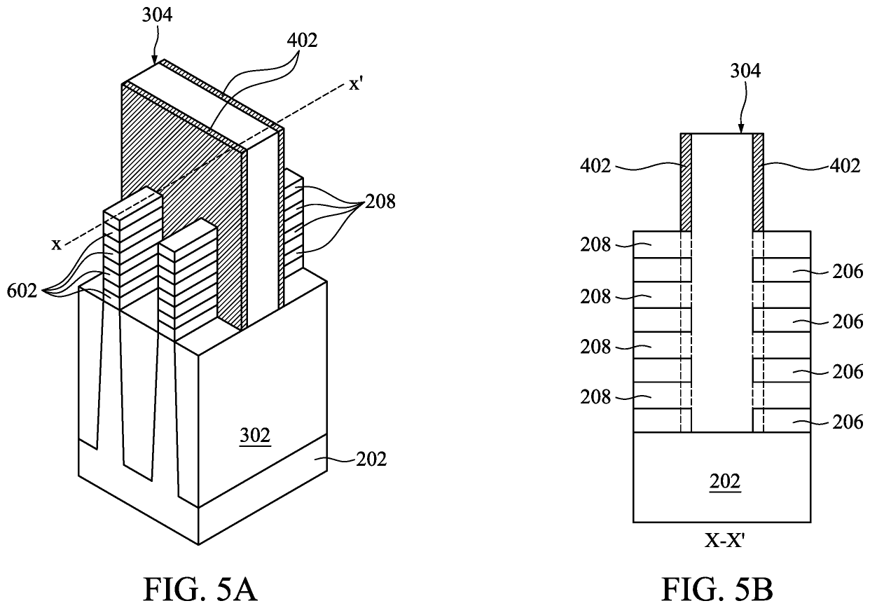

In some embodiments, the deposition of the spacer material layer is followed by an etching back (e.g., anisotropically) the dielectric spacer material. Referring to the example, with reference to the example of FIGS. 5A, 5B, after formation of the spacer material layer 402, the spacer material layer 402 may be etched-back to expose portions of the fin elements 210 adjacent to and not covered by the gate structure 304 (e.g., source/drain regions). The spacer layer material may remain on the sidewalls of the gate structure 304 forming spacer elements. In some embodiments, etching-back of the spacer layer 402 may include a wet etch process, a dry etch process, a multiple-step etch process, and/or a combination thereof. The spacer layer 402 may be removed from a top surface of the exposed epitaxial stack 204 and the lateral surfaces of the exposed epitaxial stack 204, as illustrated in FIGS. 5A and 5B.

The method 100 then proceeds to block 112 where an oxidation process is performed. The oxidation process may be referred to as a selective oxidation as due to the varying oxidation rates of the layers of the epitaxial stack 204, certain layers are oxidized. In some examples, the oxidation process may be performed by exposing the device 200 to a wet oxidation process, a dry oxidation process, or a combination thereof. In at least some embodiments, the device 200 is exposed to a wet oxidation process using water vapor or steam as the oxidant, at a pressure of about 1 ATM, within a temperature range of about 400-600° C., and for a time from about 0.5-2 hours. It is noted that the oxidation process conditions provided herein are merely exemplary, and are not meant to be limiting. It is noted that this oxidation process may in some embodiments, extend such that the oxidized portion of the epitaxial layer(s) of the stack abuts the sidewall of the gate structure 304.

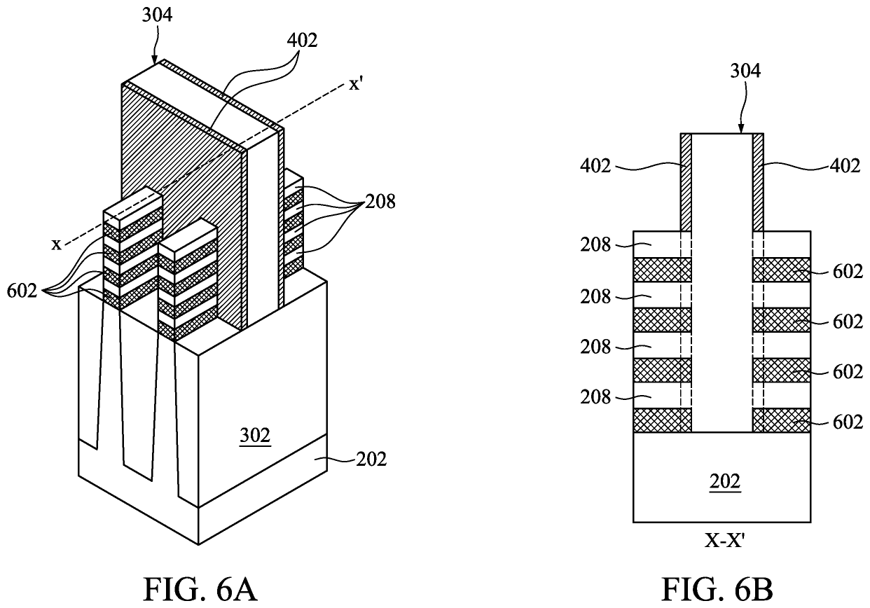

With reference to the example of FIGS. 6A and 6B, in an embodiment of block 112, the device 200 is exposed to an oxidation process that fully oxidizes the epitaxial layer 206 of each of the plurality of fin elements 210. The epitaxial layer layers 206 transform into an oxidized layer 602. The oxidized layer 602 extends to the gate structure 304, including, under the spacer elements 402. In some embodiments, the oxidized layer 602 has a thickness range of about 5 to about 25 nanometers (nm). In an embodiment, the oxidized layer 602 may include an oxide of silicon germanium (SiGeOx).

By way of example, in embodiments where the epitaxial layers 206 include SiGe, and where the epitaxial layers portion 208 includes Si, the faster SiGe oxidation rate (i.e., as compared to Si) ensures that the SiGe layer 206 becomes fully oxidized while minimizing or eliminating the oxidization of other epitaxial layers 208. It will be understood that any of the plurality of materials discussed above may be selected for each of the first and second epitaxial layer portions that provide different suitable oxidation rates.

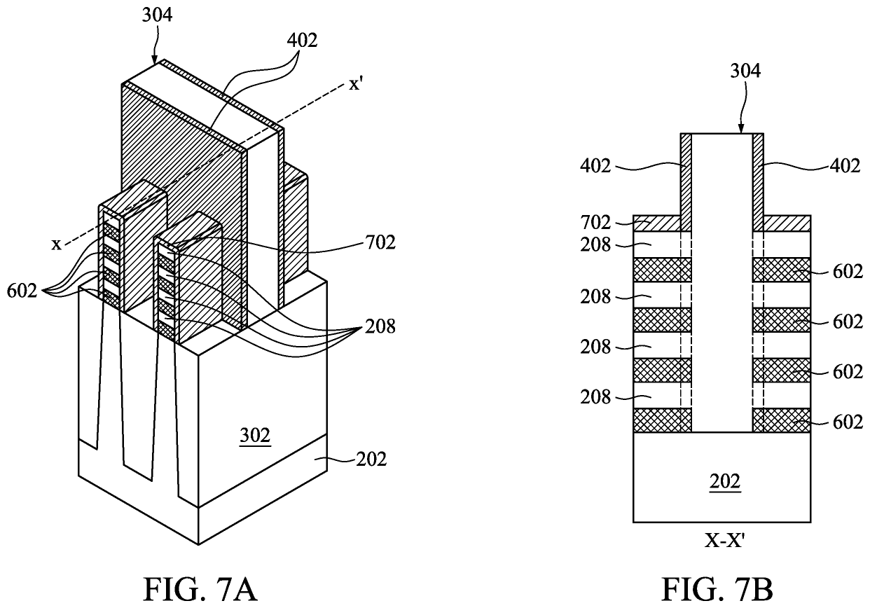

The method 100 then proceeds to block 114 where source/drain features are formed on the substrate. The source/drain features may be formed by performing an epitaxial growth process that provides an epitaxy material on the fin 210 in the source/drain region. In an embodiment, the epitaxy material of the source/drain is formed cladding the portions of the epitaxy layers remaining in the fins' source/drain regions. Referring to the example of FIGS. 7A and 7B, source/drain features 702 are formed on the substrate 202 in/on the fin 210 adjacent to and associated with the gate stack 304. The source/drain features 702 include material formed by epitaxially growing a semiconductor material on the exposed epitaxial layer 208 and/or oxidized layer 602. It is noted that the shape of the features 702 is illustrative only and not intended to be limiting; as understood by one of ordinary skill in the art, any epitaxial growth will occur on the semiconductor material (e.g., 208) as opposed to the dielectric material (e.g., 602), the epitaxial growth may be grown such that it merges over a dielectric layer (e.g., over 602) as illustrated.

In various embodiments, the grown semiconductor material of the source/drain 702 may include Ge, Si, GaAs, AlGaAs, SiGe, GaAsP, SiP, or other suitable material. In some embodiments, the material of the source/drain 702 may be in-situ doped during the epi process. For example, in some embodiments, epitaxially grown material may be doped with boron. In some embodiments, epitaxially grown material may be doped with carbon to form Si:C source/drain features, phosphorous to form Si:P source/drain features, or both carbon and phosphorous to form SiCP source/drain features. In an embodiment, the epitaxial material of the source/drain 702 is silicon and the layer 208 also is silicon. In some embodiments, the layers 702 and 208 may comprise a similar material (e.g., Si), but be differently doped. In other embodiments, the epitaxy layer for the source/drain 702 includes a first semiconductor material, the epitaxially grown material 208 includes a second semiconductor different than the first semiconductor material. In some embodiments, the epitaxially grown material of the source/drain 702 is not in-situ doped, and, for example, instead an implantation process is performed.

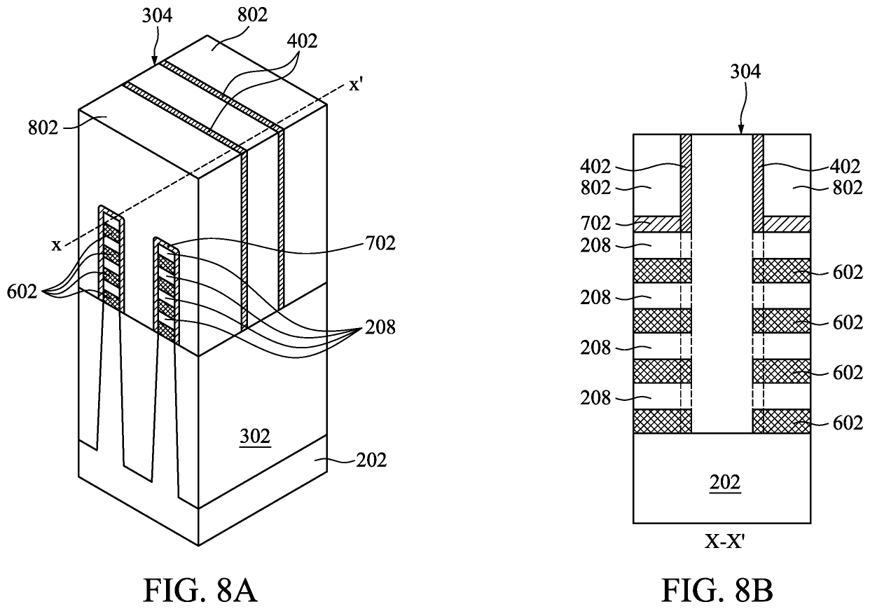

The method 100 then proceeds to block 116 where an inter-layer dielectric (ILD) layer is formed on the substrate. Referring to the example of FIGS. 8A and 8B, in an embodiment of block 116, an ILD layer 802 is formed over the substrate 202. In some embodiments, a contact etch stop layer (CESL) is also formed over the substrate 202 prior to forming the ILD layer 802. In some examples, the CESL includes a silicon nitride layer, silicon oxide layer, a silicon oxynitride layer, and/or other materials known in the art. The CESL may be formed by plasma-enhanced chemical vapor deposition (PECVD) process and/or other suitable deposition or oxidation processes. In some embodiments, the ILD layer 802 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 802 may be deposited by a PECVD process or other suitable deposition technique. In some embodiments, after formation of the ILD layer 802, the semiconductor device 200 may be subject to a high thermal budget process to anneal the ILD layer.

In some examples, after depositing the ILD (and/or CESL or other dielectric layers), a planarization process may be performed to expose a top surface of the gate stack 304. For example, a planarization process includes a chemical mechanical planarization (CMP) process which removes portions of the ILD layer 802 (and CESL layer, if present) overlying the gate stack 304 and planarizes a top surface of the semiconductor device 200.

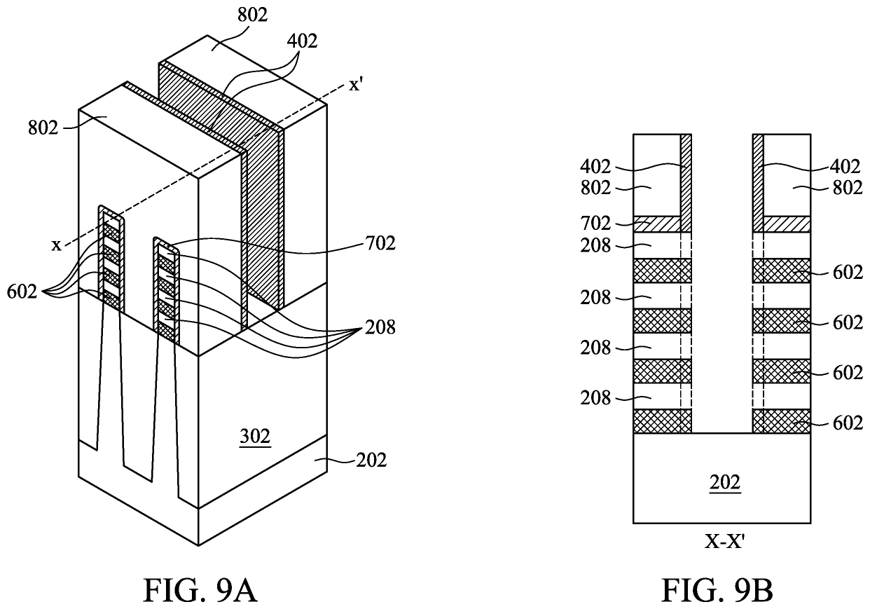

The method 100 then proceeds to block 118 where the dummy gate (see block 108) is removed. The gate electrode and/or gate dielectric may be removed by suitable etching processes. In some embodiments, block 118 also includes selective removal of the epitaxial layer(s) in the channel region of the device is provided. In embodiments, the selected epitaxial layer(s) are removed in the fin elements within the trench provided by the removal of the dummy gate electrode (e.g., the region of the fin on and over which the gate structure will be formed, or the channel region). Referring to the example of FIGS. 9A and 9B, the epitaxy layers 206 are removed from the channel region of the substrate 202 and within the trench. In some embodiments, the epitaxial layers 206 are removed by a selective wet etching process. In some embodiments, the selective wet etching includes HF. In an embodiment, the epitaxial layers 206 are SiGe and the epitaxial layers 208 are silicon allowing for the selective removal of the SiGe epitaxial layers 206.

The method 100 then proceeds to block 120 where a gate structure is formed. The gate structure may be the gate of a multi-gate transistor. The final gate structure may be a high-K/metal gate stack, however other compositions are possible. In some embodiments, the gate structure forms the gate associated with the multi-channels provided by the plurality of nanowires (now having gaps there between) in the channel region.

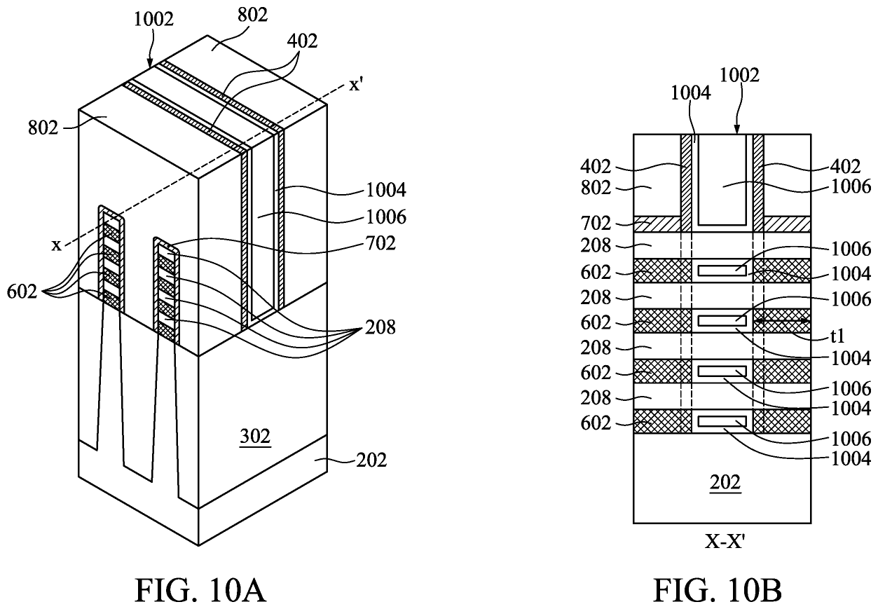

Referring to the example of FIGS. 10A and 10B, in an embodiment of block 120, a high-K/metal gate stack 1002 is formed within the trench of the device 200 provided by the removal of the dummy gate and/or release of nanowires, described above with reference to block 118. In various embodiments, the high-K/metal gate stack 1002 includes an interfacial layer, a high-K gate dielectric layer 1004 formed over the interfacial layer, and/or a metal layer 1006 formed over the high-K gate dielectric layer 1004. High-K gate dielectrics, as used and described herein, include dielectric materials having a high dielectric constant, for example, greater than that of thermal silicon oxide (˜3.9). The metal layer used within high-K/metal gate stack may include a metal, metal alloy, or metal silicide. Additionally, the formation of the high-K/metal gate stack may include depositions to form various gate materials, one or more liner layers, and one or more CMP processes to remove excessive gate materials and thereby planarize a top surface of the semiconductor device 200.

In some embodiments, the interfacial layer of the gate stack 1002 may include a dielectric material such as silicon oxide (SiO₂), HfSiO, or silicon oxynitride (SiON). The interfacial layer may be formed by chemical oxidation, thermal oxidation, atomic layer deposition (ALD), chemical vapor deposition (CVD), and/or other suitable method. The gate dielectric layer 1004 of the gate stack 1002 may include a high-K dielectric layer such as hafnium oxide (HfO₂). Alternatively, the gate dielectric layer 1004 of the gate stack 1002 may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable material. The high-K gate dielectric layer 1002 may be formed by ALD, physical vapor deposition (PVD), CVD, oxidation, and/or other suitable methods. The metal layer of the high-K/metal gate stack 1002 may include a single layer or alternatively a multi-layer structure, such as various combinations of a metal layer with a selected work function to enhance the device performance (work function metal layer), a liner layer, a wetting layer, an adhesion layer, a metal alloy, or a metal silicide. By way of example, the metal layer of gate stack 1002 may include Ti, Ag, Al, TiAlN, TaC, TaCN, TaSiN, Mn, Zr, TiN, TaN, Ru, Mo, Al, WN, Cu, W, Re, Ir, Co, Ni, other suitable metal materials or a combination thereof. In various embodiments, the metal layer of the gate stack 1002 may be formed by ALD, PVD, CVD, e-beam evaporation, or other suitable process. Further, the metal layer of the gate stack 1002 may be formed separately for N-FET and P-FET transistors which may use different metal layers. In various embodiments, a CMP process may be performed to remove excessive metal from the metal layer of the gate stack 1002, and thereby provide a substantially planar top surface of the metal layer of the gate stack 1002. The metal layer 1006 of the gate stack 1002 is illustrated in FIGS. 10A and 10B. In addition, the metal layer may provide an N-type or P-type work function, may serve as a transistor (e.g., FinFET) gate electrode, and in at least some embodiments, the metal layer of the gate stack 1002 may include a polysilicon layer. The gate structure 1002 includes portions that interpose each of the epitaxial layers 306, which each form channels of the multi-gate device 200.

The method 100 then proceeds to block 122 wherein further fabrication is performed. A semiconductor device may undergo further processing to form various features and regions known in the art. For example, subsequent processing may form contact openings, contact metal, as well as various contacts/vias/lines and multilayers interconnect features (e.g., metal layers and interlayer dielectrics) on the substrate, configured to connect the various features to form a functional circuit that may include one or more multi-gate devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 100, and some process steps described above may be replaced or eliminated in accordance with various embodiments of the method 100.

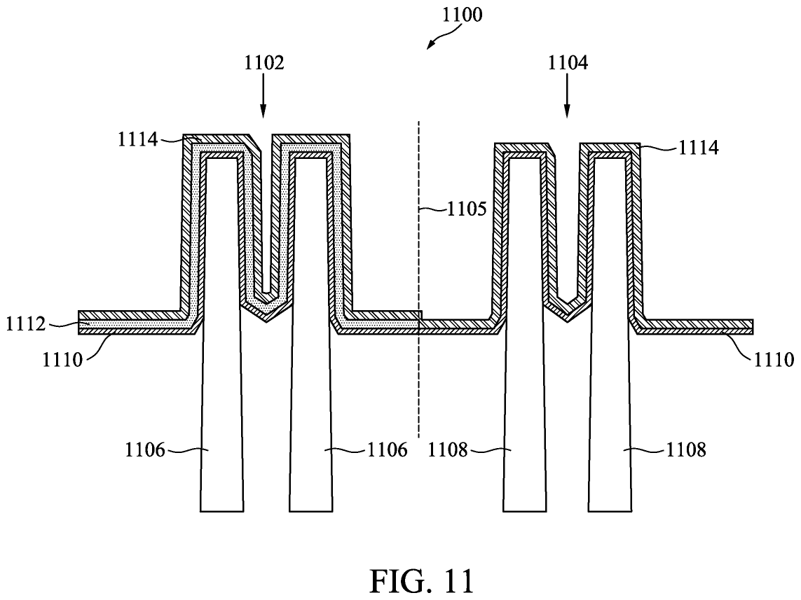

FIG. 11 schematically illustrates another example semiconductor structure 1100 in a two-dimensional view at one stage during fabrication of a semiconductor device. Other aspects not illustrated in or described with respect to FIG. 11 may become apparent from the following figures and description. The semiconductor structure 1100 may be part of an IC, such as a microprocessor, memory cell (such as static random-access memory (SRAM)), and/or other integrated circuits. In some embodiments, the semiconductor structure 1100 includes P-type structures 1102 and N-type structures 1104 separated at a boundary 1105. In the depicted example, the P-type structures 1102 include two epitaxial growth layers 1106 for p-type field effect transistors (FETs) (referred to herein as p-EPI layers) formation, and the N-type structures 1104 include two epitaxial growth layers 1108 for n-type FETs (referred to herein as n-EPI layers). The depicted example EPI layers 1106, 1108 are intermediate structures during fabrication of non-planar FETs such as gate-all-around (GAA) FETs, fin field-effect transistor (FinFETs), or others.

Deposited around the example EPI layers 1106, 1108 are an interfacial layer (IL) 1110 with a high K value and gate material. The gate material is patterned such that the gate material deposited over the p-EPI layers 1106 include both a first work function metal layer 1112 and a second metal layer 1114. The first work function metal layer 1112 is configured to set a stable threshold voltage (Vt) for the p-type FETs that are constructed from the p-EPI layers 1106.

Through patterning operations, the gate material deposited over the n-EPI layers 1108 do not include the first work function metal layer 1112 but do include the second metal layer 1114. The patterning operations may include depositing the first work function metal layer 1112 over the P-type structures 1102 and N-type structures 1104, depositing a hard mask over the P-type structures 1102 and N-type structures 1104, removing the hard mask from the N-type structures 1104, removing the first work function metal layer 1112 from the N-type structures 1104 via anisotropic wet etching operations, and depositing the second metal layer 1114 over the P-type structures 1102 and N-type structures 1104.

Removing the first work function metal layer 1112 from the N-type structures 1104 via wet etching operations can have the potential to damage the first work function metal layer 1112 that remains over the P-type structures 1102. From the device performance and yield aspect, if the metal boundary for the first work function metal layer 1112 is not located at its target (e.g., boundary 1105), threshold voltage (Vt) imbalance can occur. Moreover, lateral etching can damage the first work function metal layer 1112 with a dramatic decrease in yield.

Using the techniques described herein, wet etching operations to remove the first work function metal layer 1112 from the N-type structures 1104 results in the first work function metal layer 1112 remaining intact or substantially intact in the P-type structures 1102. Using the techniques described herein, an elimination or near elimination of metal loss resulting from unwanted lateral etching effects that can occur with isotropic wet etching techniques particularly at the boundary 1105 of the P-type structures 1102 can be obtained. Using the techniques described herein, an elimination or near elimination of metal loss resulting from unwanted etchant chemical leakage through hard mask material due to polar effects between the chemical etchant and the porous hard mask material can be obtained.

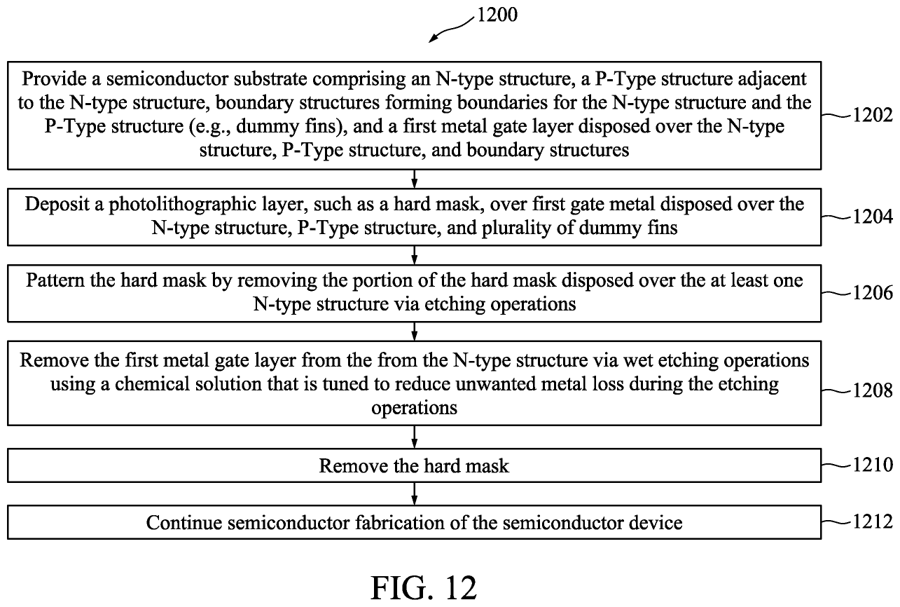

FIG. 12 is a process flow chart depicting an example process 1200 for forming gate metal around a multi-gate device in a semiconductor device, according to various aspects of the present disclosure. As used herein, the term “multi-gate device” is used to describe a device (e.g., a semiconductor transistor) that has at least some gate material disposed on multiple sides of at least one channel of the device. In some examples, the multi-gate device may be referred to as a GAA device having gate material disposed on four sides of at least one channel member of the device. The channel member may be referred to as a “nanosheet”.

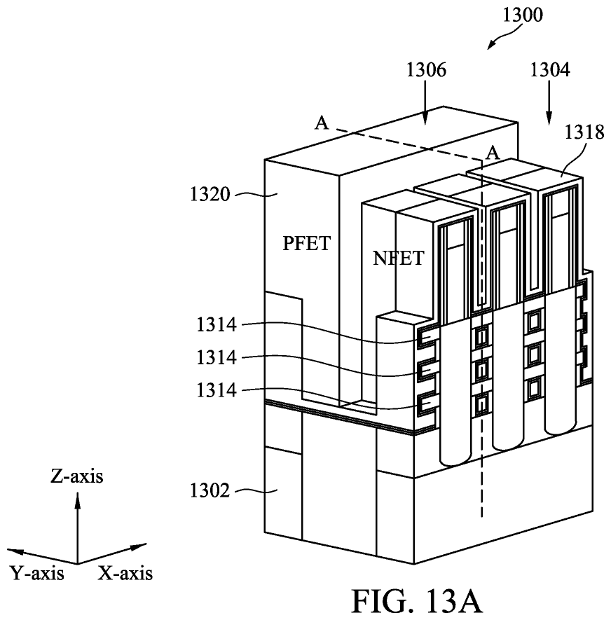

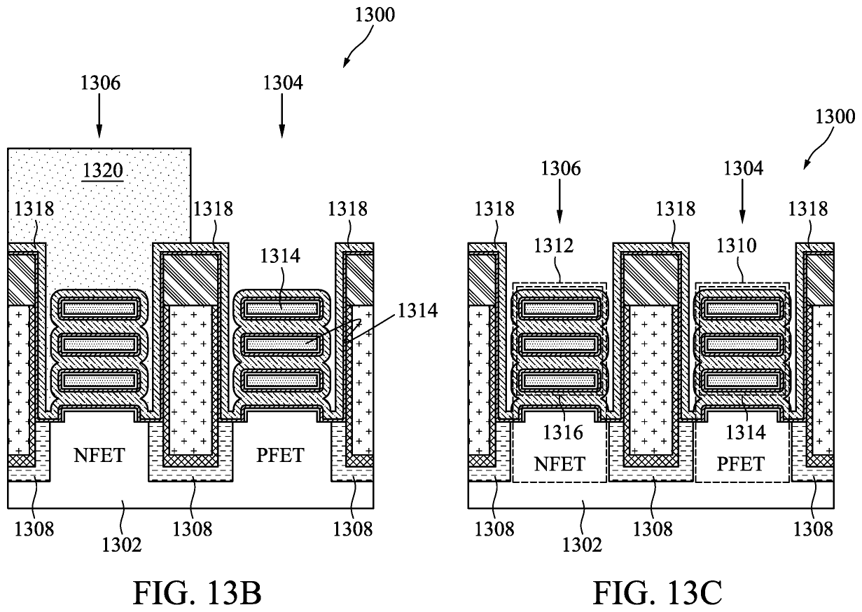

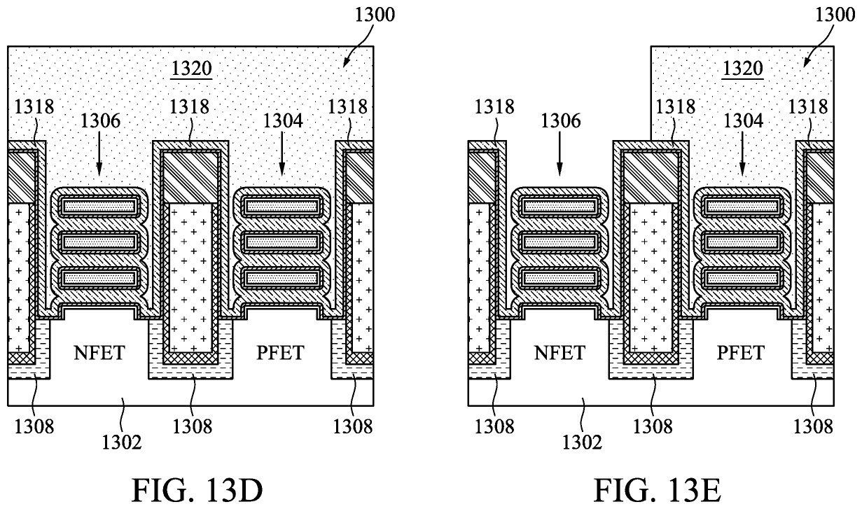

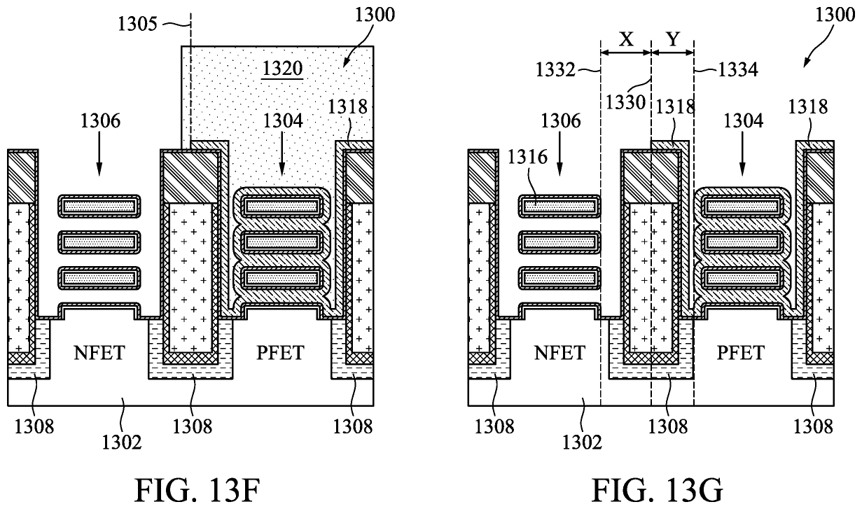

FIG. 12 is described in conjunction with FIGS. 13C-13G, which are cross-sectional views of a 3-D (three dimensional) semiconductor device 1300 depicted in FIG. 13A (at one stage of fabrication), taken along a cut line A-A along the y-axis, which illustrate the semiconductor device 1300 at various stages of fabrication in accordance with some embodiments of the present disclosure of the example process 1200. The process 1200 is merely an example, and is not intended to limit the present disclosure beyond what is explicitly recited in the claims. Additional steps may be provided before, during, and after example process 1200, and some of the steps described can be moved, replaced, or eliminated for additional embodiments of example process 1200. Additional features may be added in the semiconductor device depicted in the Figures and some of the features described below can be replaced, modified, or eliminated in other embodiments of the semiconductor device.

It is understood that parts of the semiconductor device 1300 may be fabricated by typical semiconductor technology process flow, and thus some processes are only briefly described herein. Further, the exemplary semiconductor devices may include various other devices and features, such as other types of devices such as additional transistors, bipolar junction transistors, resistors, capacitors, inductors, diodes, fuses, and/or other logic devices, etc., but is simplified for a better understanding of concepts of the present disclosure. In some embodiments, the exemplary devices include a plurality of semiconductor devices (e.g., transistors), including PFETs, NFETs, etc., which may be interconnected. Moreover, it is noted that the operations of process 1200, including any descriptions given with reference to the Figures are merely exemplary and are not intended to be limiting beyond what is specifically recited in the claims that follow.

With reference to FIG. 13A, an example 3-D semiconductor device 1300 is depicted that includes N-type structures (e.g., NFETs) 1306 and P-Type structures (PFETs) 1304 disposed over a semiconductor substrate 1302. Metal gate material 1318 is disposed over the N-type structures and a photolithographic layer 1320 (e.g., a hard mask), such as a bottom anti-reflective coating (BARC) or photoresist (PR) material is disposed over the P-Type structures. The 3-D semiconductor device 1300 includes a channel region 1314 in the N-type structures 1306 containing 3 channels.

FIG. 13B is a cross-sectional view of the 3-D (three dimensional) semiconductor device 1300. It also includes N-type structures (e.g., NFETs) 1306 and P-Type structures (PFETs) 1304 disposed over a semiconductor substrate 1302. Metal gate material 1318 is disposed over the N-type structures 1306 and a photolithographic layer 1320 (e.g., a hard mask), such as a bottom anti-reflective coating (BARC) or photoresist (PR) material is disposed over the P-Type structures 1304. The semiconductor device 1300 includes a channel region 1314 in the N-type structures 1306 containing 3 channels.

The example process 1200 includes (at block 1202) providing a semiconductor substrate comprising an N-type structure, a P-Type structure adjacent to the N-type structure, boundary structures forming boundaries for the N-type structure and the P-Type structure (e.g., a plurality of dummy fins forming boundaries for the at least one N-type structure and the at least one P-Type structure), and a first metal gate layer disposed over the N-type structure, P-Type structure, and boundary structures.

Referring to the example of FIG. 13C, in an embodiment of block 1202, the example semiconductor device 1300 at this stage of gate fabrication includes a semiconductor substrate 1302 having a P-type structure 1304, an N-type structure 1306 immediately adjacent to the P-type structure 1304, and a plurality of dummy fins 1308 for bounding the P-type structure 1304 and the N-type structure 1306. The P-type structure 1304 comprises an p-EPI layer 1310, and the N-type structure 1306 comprises a n-EPI layer 1312. The p-EPI layer 1310 comprises a vertical slice of the substrate in a p-type region plus one or more channel regions 1314 (3 in this example) disposed above the vertical slice of the substrate in the p-type region. Similarly, the n-EPI layer 1312 comprises a vertical slice of the substrate in an n-type region plus one or more channel regions 1316 (3 in this example) disposed above the vertical slice of the substrate in the n-type region. A first type of metal gate material 1318 has been deposited over the at least one N-type structure 1306, at least one P-Type structure 1304, and dummy fins 1308. The metal gate material 1318 may have been deposited by chemical vapor deposition (CVD), physical vapor deposition (PVD), atomic layer deposition (ALD), or another deposition technique.

The metal gate material 1318 in this example comprises a work function metal layer. The metal gate material 1318 may include a transition metal (e.g., Ti, W, V, Nb, Mn, Mo) or any suitable materials or a combination thereof. A work function value is associated with the material composition of the work function metal layer. The material of the work function metal layer is chosen to tune a work function value so that a desired threshold voltage (Vt) is achieved in the device that is to be formed in the respective region. The metal gate material 1318 may be deposited by CVD, ALD and/or other suitable processes so that the work function metal layer provides uniform threshold voltage (Vt). In one embodiment, the metal gate material 1318 is formed by an ALD process. In one embodiment, the ALD process may be followed by an anneal process. In one embodiment, the ALD film may be annealed at a temperature at about 850° C. In one embodiment, the metal gate material 1318 has a thickness from 0.5 to 20 nm. The thickness of the metal gate material 1318 may be altered and adjusted by altering process parameters during the ALD deposition process, such as the deposition time, number of the pulses of precursors, pulse frequency, substrate temperature, pressure, and the like. Even though only one layer of material is shown in the metal gate material 1318 discussed in the present disclosure, the metal gate material 1318 may include a combination of multiple layers.

With reference to FIG. 12, the example process 1200 includes (at block 1204) depositing a photolithographic layer, such as a hard mask, over first gate metal disposed over the at least one N-type structure, at least one P-Type structure, and plurality of dummy fins. In various embodiments, the photolithographic layer comprises an organic hard mask (e.g., photoresist). In various embodiments, the photolithographic layer comprises inorganic hard mask (e.g., Aluminum oxide).

Referring to the example of FIG. 13D, in an embodiment of block 1204, the example semiconductor device 1300 at this stage of gate fabrication includes a photolithographic layer 1320 (e.g., a hard mask), such as a bottom anti-reflective coating (BARC) or photoresist (PR) material, disposed over the metal gate material 1318 disposed over the at least one N-type structure 1306, at least one P-Type structure 1304, and plurality of dummy fins 1308.

With reference to FIG. 12, the example process 1200 includes (at block 1206) patterning the hard mask by removing the portion of the hard mask disposed over the at least one N-type structure via etching operations. A photolithography process is performed to form patterned layers over the device 1300. The patterned layers may include a bottom anti-reflective coating (BARC) and a photoresist layer. The BARC layer may be an organic material coated onto the substrate filling trenches and then removed from portions of the substrate after patterning, such as by using photolithography with the photoresist layer. In one embodiment, the patterned layers expose certain regions, such as regions corresponding to the N-type FinFET structure 304 to allow processing over regions of the N-type FinFET structure 304 while leaving the remaining regions intact.

Referring to the example of FIG. 13E, in an embodiment of block 1206, the example semiconductor device 1300 at this stage of gate fabrication includes the hard mask 1320 disposed over the metal gate material 1318 disposed over the at least one P-Type structure 1304 but removed from metal gate material 1318 disposed over the at least one N-Type structure 1306.

With reference to FIG. 12, the example process 1200 includes (at block 1208) removing the first metal gate layer from the from the N-type structure via wet etching operations using a chemical solution that is tuned to reduce metal loss during the etching operations. For example, the etching process may be performed by dipping, immersing, or soaking the substrate with or in an etching solution in a wet tank. The etching solution may be an alkaline, neutral, or acid solution with a pH value in a predetermined range. Selection of the etching solution is based on the materials in the first metal layer and the materials in the hard mask. In particular, the etching solution is selected based on molecular weight (MW) tuning, steric effect tuning, and polarity tuning to create a protection layer to prevent unwanted metal loss in regions disposed under the hard mask.

Referring to the example of FIG. 13F, in an embodiment of block 1208, the example semiconductor device 1300 at this stage of gate fabrication has the first metal gate layer removed from the N-type structure 1306 via wet etching operations using a chemical solution that is tuned to reduce metal loss during the etching operations. In the depicted example, the first metal gate layer disposed over the at least one P-Type structure 1304 extends to a boundary 1305 between the P-Type structure 1304 and the N-Type structure 1306 without metal loss inside the boundary of the P-Type structure 304 (or insignificant metal loss wherein Vt is not adversely affected).

With reference to FIG. 12, the example process 1200 includes (at block 1210) removing the hard mask (e.g., BARC layer). The hard mask may be removed, for example, by an ashing process. For example, an ashing process using oxygen plasma may be used to remove the BARC layer.

Referring to the example of FIG. 13G, in an embodiment of block 1210, the example semiconductor device 1300 at this stage of gate fabrication has the hard mask (e.g., BARC layer) removed from the P-type structure 1304. The hard mask may have been removed via an ashing process. In the depicted example, the first metal layer disposed over the P-Type structure 1304 extends to the boundary 1305 between the P-Type structure 1304 and the N-Type structure 1306 without metal loss inside the boundary of the P-Type structure 1304 (or insignificant metal loss wherein Vt is not adversely affected). The remaining metal length of the first metal layer has been maintained to achieve, after the wet etch operations, a remaining metal ratio of a distance X over a distance Y (e.g., X/Y) that is less than 179 (89.5/0.5 nm) and greater than 1, wherein X is a first distance from a first line 1330 extending from an edge of the remaining metal layer over the P-Type structure 1304 to a second line 1332 extending from an edge of a channel region 1316 in the N-Type structure 1306 (which includes metal loss due to unwanted penetration of the chemical etchant into the P-Type structure 1304 during wet etching operations), and Y is a second distance from the first line 1330 to a third line 1334 extending from an edge of the metal layer formed over the channel region 1314 in the P-Type structure 1304. This can ensure that the Vt of the P-Type structure 1304 has not been adversely affected during removal of the first metal material during wet chemical etching operations. In various embodiments, 15 nm<X+Y<90 nm. In various embodiments, 14.5 nm<X−Y<89.5 nm (minimum metal is 0.5 nm).

With reference again to FIG. 12, process 1200 includes (at block 1212) continuing semiconductor fabrication of a semiconductor device. Also, additional fabrication operations not described in process 1200 can occur before, between, and after the block 1202-1212 included in process 1200. While the foregoing described systems, methods, techniques, and articles with respect to a GAA device, the disclosed systems, methods, techniques, and articles are also applicable with respect to other FinFET devices.

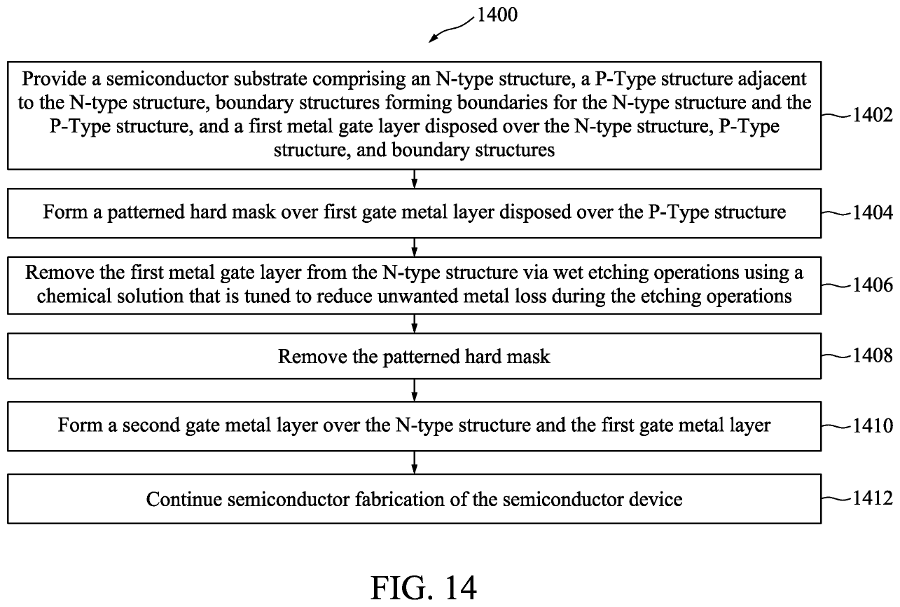

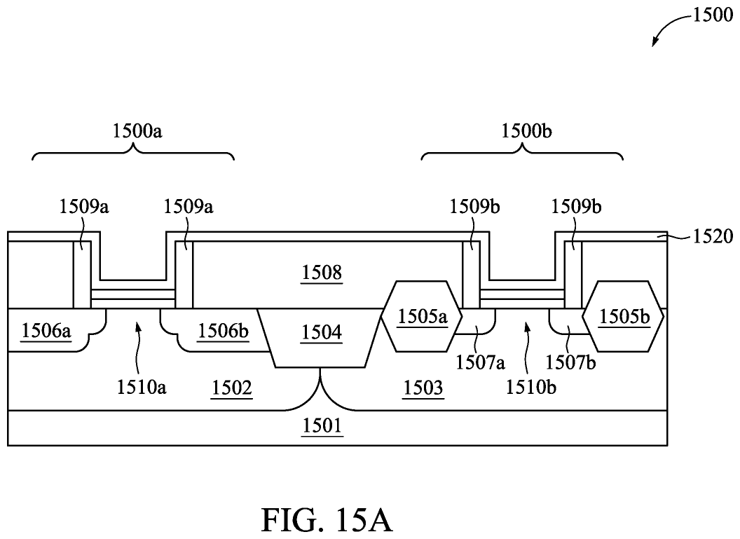

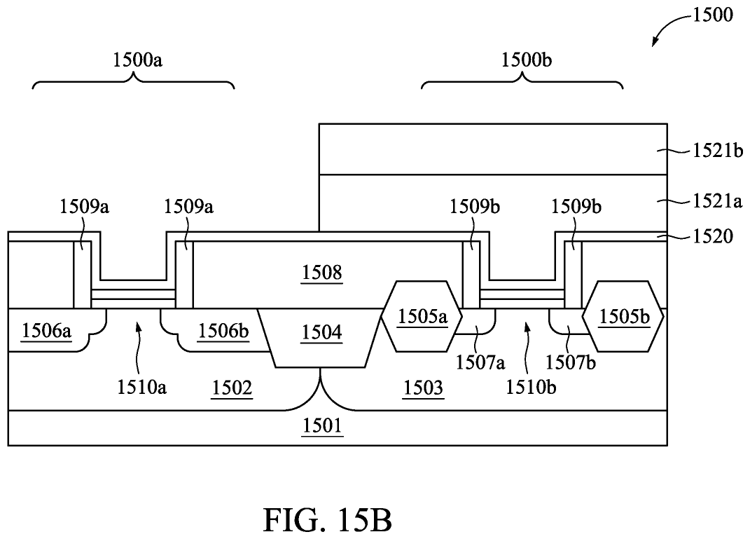

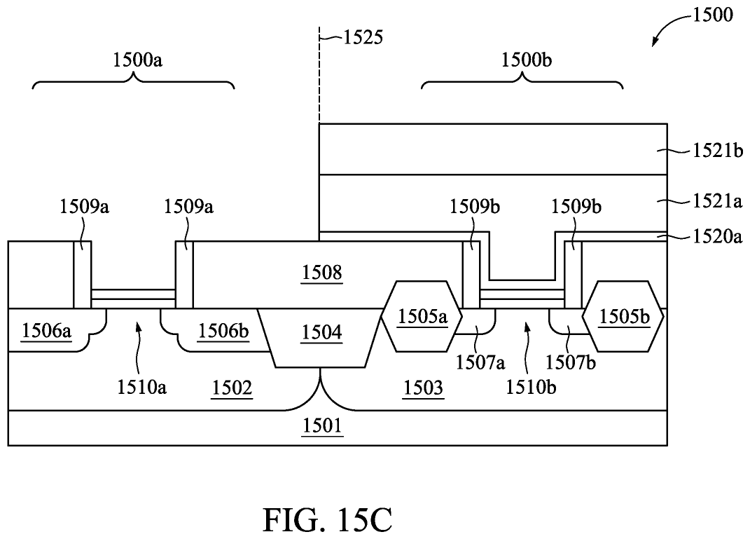

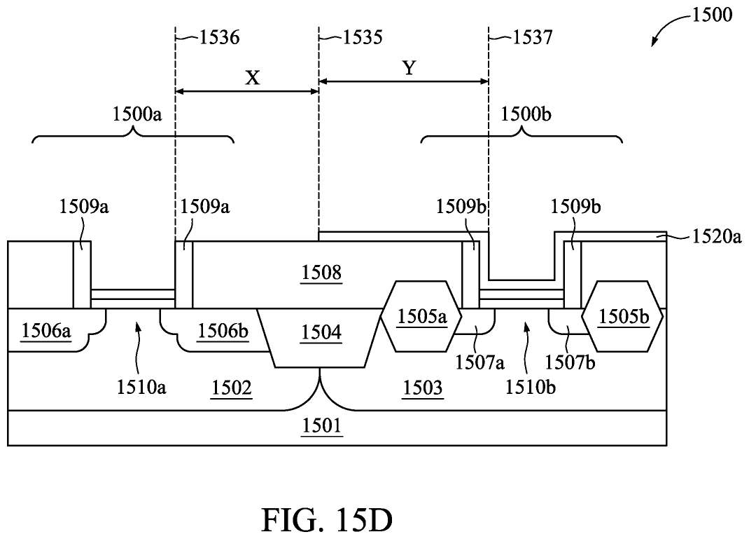

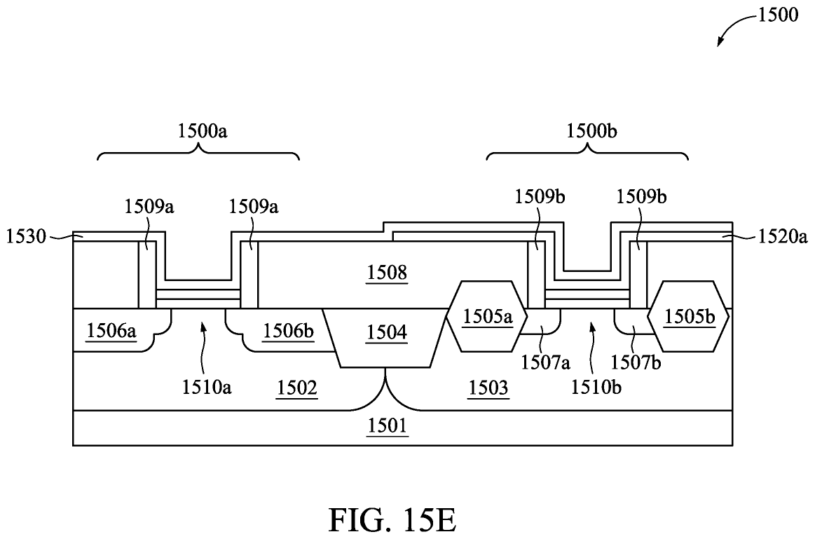

FIG. 14 is a process flow chart depicting another example process 1400 for forming gate metal around a multi-gate device in a semiconductor device, according to various aspects of the present disclosure. FIG. 14 is described in conjunction with FIGS. 15A-15E, which are cross-sectional views of another semiconductor device 1500 at various stages of fabrication in accordance with some embodiments of the present disclosure of the example process 1400. The process 1400 is merely an example, and is not intended to limit the present disclosure beyond what is explicitly recited in the claims. Additional steps may be provided before, during, and after example process 1400, and some of the steps described can be moved, replaced, or eliminated for additional embodiments of example process 1400. Additional features may be added in the semiconductor device depicted in the Figures and some of the features described below can be replaced, modified, or eliminated in other embodiments of the semiconductor device.

It is understood that parts of the semiconductor device 1500 may be fabricated by typical semiconductor technology process flow, and thus some processes are only briefly described herein. Further, the exemplary semiconductor devices may include various other devices and features, such as other types of devices such as additional transistors, bipolar junction transistors, resistors, capacitors, inductors, diodes, fuses, and/or other logic devices, etc., but is simplified for a better understanding of concepts of the present disclosure. In some embodiments, the exemplary devices include a plurality of semiconductor devices (e.g., transistors), including PFETs, NFETs, etc., which may be interconnected. Moreover, it is noted that the operations of process 1400, including any descriptions given with reference to the Figures are merely exemplary and are not intended to be limiting beyond what is specifically recited in the claims that follow.

The example process 1400 includes (at block 1402) providing a semiconductor substrate comprising an N-type structure, a P-Type structure adjacent to the N-type structure, boundary structures forming boundaries for the N-type structure and the P-Type structure (e.g., a plurality of spacers and dielectric layers forming boundaries for the at least one N-type structure and the at least one P-Type structure), and a first metal gate layer (e.g., p-type work function material) disposed over the N-type structure, P-Type structure, and boundary structures.

Referring to the example of FIG. 15A, in an embodiment of block 1402, the example semiconductor device 1500 includes a P-well region 1502 and an N-well region 1503 formed within a substrate 1501. The P-well region 1502 and the N-well region 1503 can be configured to provide channel regions of an N-type transistor 1500a and a P-type transistor 1500b, respectively.

The example semiconductor device 1500 can include an isolation structure 1504 disposed between the N-type transistor 1500a and the P-type transistor 1500b. The isolation structure 1504 can insulate the N-type transistor 1500a from the P-type transistor 1500b. In some embodiments, the isolation structure 1504 can be a shallow trench isolation (STI) structure, a local oxidation of silicon (LOCOS) structure, or other isolation structure.

In some embodiments, the P-type transistor 1500b can include silicon-germanium (SiGe) structure 1505a and 1505b disposed adjacent to p-type source/drain regions 1507a and 1507b, respectively. The p-type source/drain regions 1507a and 1507b can be disposed adjacent to the channel region of the P-type transistor 1500b. The N-type transistor 1500a can include n-type source/drain regions 1506a and 1506b disposed adjacent to the channel region of the N-type transistor 1500a.

At least one dielectric layer 1508 can be disposed over the substrate 1501. The dielectric layer 1508 may include materials such as oxide, nitride, oxynitride, low dielectric constant (low-k) dielectric material, ultra low-k dielectric material, extreme low-k dielectric material, other dielectric material, and/or combinations thereof. The dielectric layer 1508 may be formed by, for example, a CVD process, a high density plasma CVD (HDP CVD) process, a high aspect ratio process (HARP), a spin-coating process, other deposition process, and/or any combinations thereof. In some embodiments, the dielectric layer 1508 can be referred to as an interlayer dielectric (ILD). In other embodiments, additional dielectric layer (not shown) can be formed below or over the dielectric layer 1508.

In some embodiments, spacers 1509a and 1509b can be disposed adjacent to gate structures of the N-type transistor 1500a and the P-type transistor 1500b, respectively. The spacers 1509a and 1509b may include materials such as oxide, nitride, oxynitride, and/or other dielectric material.

The N-type transistor 1500a can include a gate dielectric structure 1510a disposed over a substrate 1501. The P-type transistor 1500b can include a gate dielectric structure 1510b disposed over the substrate 1501.

A p-type work function material 1520 can be formed over the structure shown in FIG. 15A. The p-type work function material 1520 can provide a desired work function value for the gate electrode of the P-type transistor 1500b. The p-type work function material 1520 can be formed by any suitable process, such as atomic layer deposition (ALD), chemical vapor deposition (CVD), physical vapor deposition (PVD), remote plasma CVD (RPCVD), plasma enhanced CVD (PECVD), metal organic CVD (MOCVD), sputtering, plating, other suitable processes, and/or combinations thereof.

With reference again to FIG. 14, the process 1400 includes (at block 1404) includes forming a patterned hard mask over first gate metal layer disposed over the P-Type structure. Referring to the example of FIG. 15B, in an embodiment of block 1404, the example semiconductor device 1500 includes a dielectric material 1521a, e.g., spin-on-glass (SOG), formed to cover the region of the P-type transistor 1500b and a photoresist 1521b defined over the dielectric material 1521a. The dielectric material 1521a and/or the photoresist 1521b can be provided for patterning the p-type work function material 1520 for the P-type transistor 1500b. The dielectric material 1521a and the photoresist 1521b can be defined by, for example, a spin-on process, a photolithographic process, and/or an etch process.

With reference again to FIG. 14, the process 1400 includes (at block 1406) removing the first metal gate layer from the N-type structure via wet etching operations using a chemical solution that is tuned to reduce unwanted metal loss during the etching operations. For example, the etching process may be performed by dipping, immersing, or soaking the substrate with or in an etching solution in a wet tank. The etching solution may be an alkaline, neutral, or acid solution with a pH value in a predetermined range. Selection of the etching solution is based on the materials in the first metal layer and the materials in the hard mask. In particular, the etching solution is selected based on molecular weight (MW) tuning, steric effect tuning, and polarity tuning to create a protection layer to prevent unwanted metal loss in regions disposed under the hard mask.

Referring to the example of FIG. 15C, in an embodiment of block 1406, a portion of the p-type work function material 1520 that is not covered by the dielectric material 1521a and the photoresist 1521b has been removed, defining the p-type work function metallic layer 1520a. The example semiconductor device 1500 at this stage of gate fabrication has the first metal gate layer removed from the N-type structure 1500a via wet etching operations using a chemical solution that is tuned to reduce unwanted metal loss during the etching operations. In the depicted example, the first metal gate layer disposed over the P-Type structure 1500b extends to a boundary 1525 between the P-Type structure 1500b and the N-Type structure 1500a without metal loss inside the boundary of the P-Type structure 1500b (or insignificant metal loss wherein Vt is not adversely affected).

With reference again to FIG. 14, the process 1400 includes (at block 1408) removing the hard mask. Referring to the example of FIG. 15D, in an embodiment of block 1408, the dielectric material 1521a and the photoresist 1521b have been removed by a wet etch process, a dry etch process, and/or combinations thereof, exposing the p-type work function metallic layer 1520a.

In the depicted example, the first metal gate layer 1520a disposed over the P-Type structure 1500b extends to the boundary 1525 between the P-Type structure 1500b and the N-Type structure 1500a without metal loss inside the boundary of the P-Type structure 1500b (or insignificant metal loss wherein Vt is not adversely affected). The remaining metal length of the first metal gate layer 1520a has been maintained to achieve, after the wet etch operations, a remaining metal ratio of a distance X over a distance Y (e.g., X/Y) that is less than 179 (89.5/0.5 nm) and greater than 1, wherein X is a first distance from a first line 1535 extending from an edge of the remaining metal layer over the P-Type structure 1500b to a second line 1536 extending from an edge of a channel region in the N-Type structure 1500a (which includes metal loss due to unwanted penetration of the chemical etchant into the P-Type structure 1500b during wet etching operations), and Y is a second distance from the first line 1535 to a third line 1537 extending from an edge of the metal layer formed over the channel region in the P-Type structure 1500b. This can ensure that the Vt of the P-Type structure 1500b has not been adversely affected during removal of the first metal gate layer during wet chemical etching operations. In various embodiments, 15 nm<X+Y<90 nm. In various embodiments, 14.5 nm<X−Y<89.5 nm (minimum metal is 0.5 nm).

With reference again to FIG. 14, the process 1400 includes (at block 1410) forming a second gate metal layer over the N-type structure and the first gate metal layer. Referring to the example of FIG. 15E, in an embodiment of block 1410, an n-type work function material 1530 has been formed over the structure. The n-type work function material 1530 can provide a desired work function value for the gate electrode of the N-type transistor 1500a. The n-type work function material 1530 can be formed by any suitable process, such as atomic layer deposition (ALD), chemical vapor deposition (CVD), physical vapor deposition (PVD), remote plasma CVD (RPCVD), plasma enhanced CVD (PECVD), metal organic CVD (MOCVD), sputtering, plating, other suitable processes, and/or combinations thereof.

With reference again to FIG. 14, process 1200 includes (at block 1412) continuing semiconductor fabrication of a semiconductor device. Also, additional fabrication operations not described in process 1400 can occur before, between, and after the blocks 1402-1412 included in process 1400.

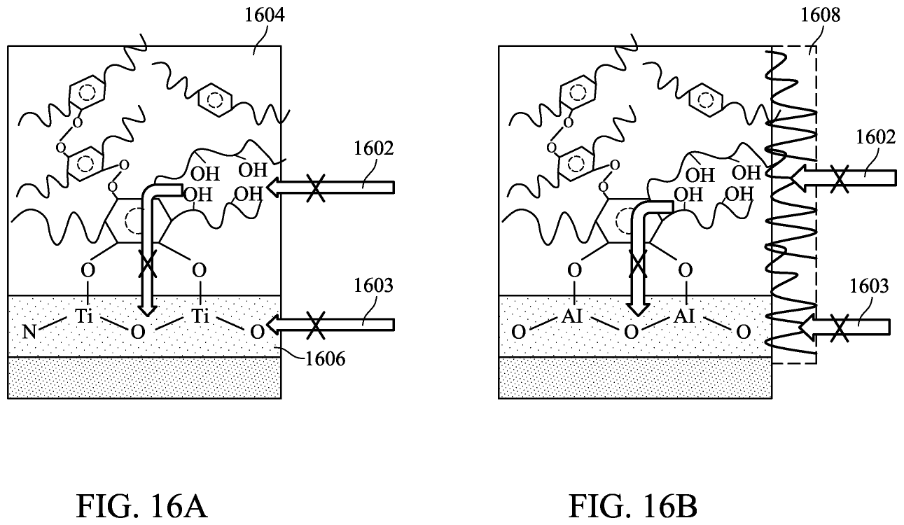

FIGS. 16A and 16B are block diagrams illustrating effects that may be achieved from chemical tuning of an etchant solution to achieve anisotropic wet etching. During isotropic wet etching operations, a chemical etchant 1602, 1603 contained in an etchant solution may be applied to a lithographic layer (e.g., hard mask 1604 such as one containing a BARC or photoresist material). For example, photoresist (PR) is a porous material, in some examples consisting of carbon, oxygen, nitrogen, and hydrogen polymer chain. Because the hard mask 1604 is porous, some of the chemical etchant 1602 can penetrate into and through the hard mask 1604 and etch away a portion of the metal layer 1606 the hard mask 1604 was intended to protect. If the chemical etchant 1603 penetrates the hard mask 1604, the chemical etchant can react with the exposed metal layer 1606 the hard mask 1604 was intended to protect, causing the metal boundary (see e.g., line 1330) to be off-target. From a device performance and yield aspect, when the metal boundary is not located on target, threshold voltage (Vt) imbalance may occur. Moreover, lateral etching by the chemical etchant 1603 can damage metal on the active region and resultantly yield could dramatically decrease.

By tuning the chemical etchant 1602, greater protection is provided to protect the metal layer 1606 the hard mask 1604 was intended to protect. Chemical tuning can result in anisotropic wet etching wherein the chemical etchant 1602, 1603 does not adversely affect the metal layer 1606 the hard mask 1604 was intended to protect. As depicted in FIG. 16B, chemical tuning may have the effect of forming a barrier 1608 that resists penetration by the chemical etchant 1602, 1603 into the hard mask 1604 and metal layer 1606 the hard mask 1604 was intended to protect.

In various embodiments, the chemical etchant is selected based on molecular weight and polarity, wherein a higher molecular weight can lead to more resistance to lithographic layer penetration and polarity change can lead to can lead to more resistance to lithographic layer penetration. Manipulating positive/negative ions and “molecular weight” can be effective in lowering and controlling unwanted diffusion into a hard mask. To decrease unwanted metal loss during wet etching operations, the water-dissolved chemicals in a chemical etchant should contain an ion pair (e.g., a positive or negative ion pair). The ion pair polarity can be selected for improved resistance to lithographic layer penetration. For example, “Polar functionalities”, such as hydroxyl group, prolong ion pair retention time in lithographic layers (e.g., photoresist) due to a polar channel trapping the chemical and therefore suppressing diffusion rate. In various embodiments, the chemical etchant is selected to achieve steric hindrance in view of the steric effect of the chemical with the lithographic layer. The “Steric effect” can enhance the effects of molecular weight and polarity in lithographic layers (e.g., porous photoresist).

In various embodiments, the chemical etchant is a solution comprising either an organic acid or organic base, plus an oxidant, and plus water (H2O). In various embodiments, when the chemical solution comprises an organic acid, the organic acid: has a molecular weight from 14 to 10⁴ g/mol, is from functional group 3, 4, 5, 6, or 7 in the Periodic table or their combination, and has a concentration ranging from 0.001 to 100 wt %. In various embodiments, when the chemical etchant comprises an organic base, the organic base: has a molecular weight from 20 to 10⁴ g/mol; is from functional group 3, 4, 5, 6, or 7 in the Periodic table or their combination; and has a concentration ranging from 0.001 to 100 wt %. In various embodiments, the oxidant (ex: H₂O₂/Ozone) has a concentration ranging from 0.1 to 10⁷ ppm.

The foregoing examples disclose wet etching operations for etching away a metal layer from an n-EPI layer and wet etching operations for removing a portion of a deposited material from one semiconductor structure while allowing the deposited material to remain on a second semiconductor structure with no or minimal boundary loss.

The described systems, methods, and techniques provide a novel diffusion inhibition solution to suppress unwanted lateral etching during wet etching operations. The described systems, methods, and techniques utilize anisotropic wet etching due to its high etching selectivity to suppress unwanted lateral etching. Lower lateral etching reduces the metal boundary effect. The described systems, methods, and techniques can be applied without residue in trenches in the semiconductor device.

A method of forming a semiconductor device having at least two different types of semiconductor structures (e.g., a p-type FinFET structure and an n-type FinFET structure) is provided in accordance with some embodiments. The method includes: forming a metal layer over a first semiconductor structure (e.g., a p-type FinFET structure) and a second semiconductor structure (e.g., an n-type FinFET structure); and forming a patterned photolithographic layer (e.g., photoresist and/or BARC layer) over the metal layer over the first semiconductor structure. The patterned photolithographic layer is achieved by: forming a photolithographic layer over the metal layer; and removing the photolithographic layer that is over the metal layer that is the over the second semiconductor structure. The method further includes: removing the metal layer from the second semiconductor structure via wet etch operations using a chemical etchant that is tuned to resist penetration into the photolithographic layer; and achieving, after the wet etch operations using the chemical etchant, a remaining metal ratio of a distance X over a distance Y (e.g., X/Y) that is less than 179 (assuming metal thickness is 0.5 nm) and greater than 1, wherein X is a first distance from a first line extending from an edge of the remaining metal layer over the first semiconductor structure to a second line extending from an edge of a channel region in the second semiconductor structure, and Y is a second distance from the first line to a third line extending from an edge of the metal layer formed over the channel region in the first semiconductor structure.

In certain embodiments of the method, the chemical etchant is selected based on molecular weight, steric effect, and polarity, wherein a higher molecular weight is more resistant to penetration.

In certain embodiments of the method, the chemical etchant is a solution including either an organic acid or organic base, plus an oxidant, and plus water (H2O).

In certain embodiments of the method, when the chemical solution includes an organic acid, the organic acid: has a molecular weight from 14 to 10⁴ g/mol; is from functional group 3, 4, 5, 6, or 7 in the Periodic table or their combination; and has a concentration ranging from 0.001 to 100 wt %.

In certain embodiments of the method, when the chemical etchant includes an organic base, the organic base: has a molecular weight from 20 to 10⁴ g/mol; is from functional group 3, 4, 5, 6, or 7 in the Periodic table or their combination; and has a concentration ranging from 0.001 to 100 wt %.

In certain embodiments of the method, the oxidant has a concentration ranging from 0.1 to 10⁷ ppm.

In certain embodiments of the method, the metal layer includes a work function metal layer for setting a threshold voltage of a transistor.

In one embodiment, the metal layer includes a transition metal (e.g., Ti, W, V, Nb, Mn, Mo).

In certain embodiments of the method, the metal layer has a thickness from 0.5 to 20 nm.

In certain embodiments of the method, the photolithographic layer includes an organic hard mask (e.g., photoresist).

In certain embodiments of the method, the photolithographic layer includes inorganic hard mask (e.g., Aluminum oxide).

A method of forming a semiconductor device having at least two different types of semiconductor structures (e.g., a p-type FinFET structure and an n-type FinFET structure) is provided in accordance with some embodiments. The method includes: forming a metal layer over a first semiconductor structure (e.g., a p-type FinFET structure) and a second semiconductor structure (e.g., an n-type FinFET structure); and forming a patterned photolithographic layer (e.g., photoresist and/or BARC layer) over the metal layer over the first semiconductor structure. The forming the patterned photolithographic layer is achieved by: forming a photolithographic layer over the metal layer; and removing the photolithographic layer that is over the metal layer that is the over the second semiconductor structure. The method further includes: removing the metal layer from the second semiconductor structure via wet etch operations using a chemical etchant that is selected based on molecular weight, steric effect, and polarity to resist penetration into the photolithographic layer, wherein the chemical etchant is a solution including an organic acid, an oxidant, and water (H2O); and achieving, after the wet etch operations using the chemical etchant, a remaining metal ratio of a distance X over a distance Y (e.g., X/Y) that is less than 179 and greater than 1, wherein X is a first distance from a first line extending from an edge of the remaining metal layer over the first semiconductor structure to a second line extending from an edge of a channel region in the second semiconductor structure, and Y is a second distance from the first line to a third line extending from an edge of the metal layer formed over the channel region in the first semiconductor structure.

In certain embodiments of the method, the organic acid: has a molecular weight from 14 to 10⁴ g/mol; is from functional group 3, 4, 5, 6, or 7 in the Periodic table or their combination; and has a concentration ranging from 0.001 to 100 wt %.

A method of forming a semiconductor device having at least two different types of semiconductor structures (e.g., a p-type FinFET structure and an n-type FinFET structure) is provided in accordance with some embodiments. The method includes: forming a metal layer over a first semiconductor structure (e.g., a p-type FinFET structure) and a second semiconductor structure (e.g., an n-type FinFET structure); and forming a patterned photolithographic layer (e.g., photoresist and/or BARC layer) over the metal layer over the first semiconductor structure. The forming the patterned photolithographic layer is achieved by: forming a photolithographic layer (e.g., photoresist and/or BARC layer) over the metal layer; and removing the photolithographic layer that is over the metal layer that is the over the second semiconductor structure. The method further includes: removing the metal layer from the second semiconductor structure via wet etch operations using a chemical etchant that is selected based on molecular weight, steric effect, and polarity to resist penetration into the photolithographic layer, wherein the chemical etchant is a solution including an organic base, an oxidant, and water (H2O); and achieving, after the wet etch operations using the chemical etchant, a remaining metal ratio of a distance X over a distance Y (e.g., X/Y) that is less than 179 and greater than 1, wherein X is a first distance from a first line extending from an edge of the remaining metal layer over the first semiconductor structure to a second line extending from an edge of a channel region in the second semiconductor structure, and Y is a second distance from the first line to a third line extending from an edge of the metal layer formed over the channel region in the first semiconductor structure.

In certain embodiments of the method, the organic base: has a molecular weight from 20 to 10⁴ g/mol; is from functional group 3, 4, 5, 6, or 7 in the Periodic table or their combination; and has a concentration ranging from 0.001 to 100 wt %.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device having at least two different types of semiconductor structures, the method comprising:
forming a metal layer over a first semiconductor structure and a second semiconductor structure;
forming a patterned photolithographic layer over the metal layer over the first semiconductor structure by:
forming a photolithographic layer over the metal layer; and
removing the photolithographic layer that is over the metal layer that is the over the second semiconductor structure;
removing the metal layer from the second semiconductor structure via wet etch operations using a chemical etchant that is tuned to resist penetration into the photolithographic layer; and
achieving, after the wet etch operations using the chemical etchant, a remaining metal ratio of a distance X over a distance Y that is less than 179 and greater than 1, wherein X is a first distance from a first line extending from an edge of the remaining metal layer over the first semiconductor structure to a second line extending from an edge of a channel region in the second semiconductor structure, and Y is a second distance from the first line to a third line extending from an edge of the metal layer formed over the channel region in the first semiconductor structure.

2. The method of claim 1, wherein the chemical etchant is selected based on molecular weight, steric effect, and polarity, wherein a higher molecular weight is more resistant to penetration.

3. The method of claim 2, wherein the chemical etchant is a solution comprising either an organic acid or organic base, plus an oxidant, and plus water.

4. The method of claim 3, wherein when the chemical solution comprises an organic acid the organic acid:
has a molecular weight from 14 to 10⁴ g/mol;
is from functional group 3, 4, 5, 6, or 7 in the Periodic table or their combination; and
has a concentration ranging from 0.001 to 100 wt %.

5. The method of claim 3, wherein when the chemical etchant comprises an organic base the organic base:
has a molecular weight from 20 to 10⁴ g/mol;
is from functional group 3, 4, 5, 6, or 7 in the Periodic table or their combination; and
has a concentration ranging from 0.001 to 100 wt %.

6. The method of claim 3, wherein the oxidant has a concentration ranging from 0.1 to 10⁷ ppm.

7. The method of claim 1, wherein the metal layer comprises a work function metal layer for setting a threshold voltage of a transistor.

8. The method of claim 1, wherein the metal layer comprises a transition metal.

9. The method of claim 1, wherein the metal layer has a thickness from 0.5 to 20 nm.

10. The method of claim 1, wherein the photolithographic layer comprises an organic hard mask.

11. The method of claim 1, wherein the photolithographic layer comprises inorganic hard mask.

12. A method of forming a semiconductor device having at least two different types of semiconductor structures, the method comprising:
forming a metal layer over a first semiconductor structure and a second semiconductor structure;
forming a patterned photolithographic layer over the metal layer over the first semiconductor structure by:
forming a photolithographic layer over the metal layer; and
removing the photolithographic layer that is over the metal layer that is the over the second semiconductor structure;
removing the metal layer from the second semiconductor structure via wet etch operations using a chemical etchant that is selected based on molecular weight, steric effect, and polarity to resist penetration into the photolithographic layer, wherein the chemical etchant is a solution comprising an organic acid, an oxidant, and water; and
achieving, after the wet etch operations using the chemical etchant, a remaining metal ratio of a distance X over a distance Y that is less than 179 and greater than 1, wherein X is a first distance from a first line extending from an edge of the remaining metal layer over the first semiconductor structure to a second line extending from an edge of a channel region in the second semiconductor structure, and Y is a second distance from the first line to a third line extending from an edge of the metal layer formed over the channel region in the first semiconductor structure.

13. The method of claim 12, wherein the organic acid:
has a molecular weight from 14 to 10⁴ g/mol;
is from functional group 3, 4, 5, 6, or 7 in the Periodic table or their combination; and
has a concentration ranging from 0.001 to 100 wt %.

14. The method of claim 12, wherein the metal layer comprises a transition metal and has a thickness from 0.5 to 20 nm.

15. The method of claim 12, wherein the photolithographic layer comprises an organic hard mask.

16. The method of claim 12, wherein the photolithographic layer comprises inorganic hard mask.

17. A method of forming a semiconductor device having at least two different types of semiconductor structures, the method comprising:
forming a metal layer over a first semiconductor structure and a second semiconductor structure;
forming a patterned photolithographic layer over the metal layer over the first semiconductor structure by:
forming a photolithographic layer over the metal layer; and
removing the photolithographic layer that is over the metal layer that is the over the second semiconductor structure;
removing the metal layer from the second semiconductor structure via wet etch operations using a chemical etchant that is selected based on molecular weight, steric effect, and polarity to resist penetration into the photolithographic layer, wherein the chemical etchant is a solution comprising an organic base, an oxidant, and water; and
achieving, after the wet etch operations using the chemical etchant, a remaining metal ratio of a distance X over a distance Y that is less than 179 and greater than 1, wherein X is a first distance from a first line extending from an edge of the remaining metal layer over the first semiconductor structure to a second line extending from an edge of a channel region in the second semiconductor structure, and Y is a second distance from the first line to a third line extending from an edge of the metal layer formed over the channel region in the first semiconductor structure.

18. The method of claim 17, wherein the organic base:
has a molecular weight from 20 to 10⁴ g/mol;
is from functional group 3, 4, 5, 6, or 7 in the Periodic table or their combination; and
has a concentration ranging from 0.001 to 100 wt %.

19. The method of claim 17, wherein the metal layer comprises a transition metal and has a thickness from 0.5 to 20 nm.

20. The method of claim 17, wherein the photolithographic layer comprises an organic hard mask or inorganic hard mask.
